(19) United States
(12) Patent Application Publication
(10) Pub. No.: US 2022/0196221 A1
(43) Pub. Date: Jun. 23, 2022

(54) SOLID STATE BEAMFORMING HEADLAMPS

(71) Applicant: Magna Closures Inc., Newmarket (CA)

(72) Inventors: Gabriele Wayne SABATINI, Newmarket (CA); Miu TRAIAN, Newmarket (CA)

(21) Appl. No.: 17/606,072

(22) PCT Filed: May 12, 2020
(86) PCT No.: PCT/CA2020/050642

§ 371 Date: Oct. 25, 2021

Related U.S. Application Data
(60) Provisional application No. 62/846,910, filed on May 13, 2019.

(51) Int. Cl. F21S 41/663; F21S 41/153; F21S 41/265; F21S 41/20

(52) U.S. Cl. CPC F21S 41/663; F21S 41/285; F21S 41/265; F21S 41/153

(57) ABSTRACT

A vehicle lamp including a plurality of solid state light emitters and mircrolenses or microprisms optically connected to the light emitters. A base layer is configured to be adhered to a vehicle component (e.g., body) and support the solid state light emitters and the microprism layer. The microprism layer is optically connected to the matrix of solid state light emitters. A plurality of light direction controlling structures in the microprism layer can each control the direction of the light emitted from the solid state emitters and/or their lumen output levels from the lamp. Controller circuitry is provided to control solid state light emitters and/or the controllable elements of microprism layer.

### FIELD

The present disclosure relates to generally to vehicle lamps having controllable elements to direct the light beam.

### BACKGROUND

Motor vehicle headlamps have shifted from incandescent lamps and high intensity discharge lamps (e.g., xenon electrical gas-discharge lamps) to more electrically efficient light emitting diode (LED) lamps. LED lamps typically provide greater lumens for less electrical energy, e.g., by producing less infrared or red bandwidth light as well as less heat. However, LED lamps provide a wide light beam and can create unwanted glare for oncoming vehicles.

### SUMMARY

This section provides a general summary of the present disclosure and is not a comprehensive disclosure of its full scope or all of its features, aspects and objectives.

In accordance with one aspect of the disclosure, a lamp is provided that includes structures to guide the light from individual light sources to control the light beam emitted from the lamp. In an example embodiment, a matrix of light sources, e.g., solid state light sources such as light emitting diodes, is provided. A corresponding matrix of light controlling devices, e.g., solid state devices, lenses, prisms, is optically coupled to the matrix of light sources to beam form the light emitted from the lamp. In an example embodiment, the matrix of light controlling devices is a one-to-one match with the matrix of light sources. In an example embodiment, the matrix of light controlling devices is a one-to-a small plurality match with the matrix of light sources.

In accordance with an aspect of the disclosure, a vehicle lamp includes a matrix of solid state light emitters and a lens optically connected to the matrix of solid state light emitters, wherein the lens includes a plurality of controllable refractory devices. A controller is provided to control the matrix of solid state light emitters and the plurality of refractory devices.

In accordance with an aspect of the disclosure, the solid state light emitters are each individually controllable.

In accordance with an aspect of the disclosure, the refractory devices are microlenses.

In accordance with an aspect of the disclosure, the refractory devices are each individually controllable to control the direction of the light beams from the lamp.

In accordance with an aspect of the disclosure, the controller receives position information of another vehicle and controls direction of the light by controlling the refractory devices to direct light away from the another vehicle.

In accordance with an aspect of the disclosure, the refractory devices include liquid crystal lenses.

In accordance with an aspect of the disclosure, the solid state light emitters are controlled to adjust the lumens being output from each light source.

In accordance with an aspect of the disclosure, a vehicle lamp comprises a base layer configured to be adhered to a vehicle component, a thin film active layer including a matrix of solid state light emitters, and a microprism layer optically connected to the matrix of solid state light emitters. Each solid state emitter is optically coupled to at least one microprism of the microprism layer to control the direction of the light emitted from the lamp. Controller circuitry controls the matrix of solid state light emitters.

In accordance with an aspect of the disclosure, the controller circuitry controls the on state of each solid state emitter.

In accordance with an aspect of the disclosure, the controller circuitry receives sensed signals from vehicle sensors and controls operation of each solid state emitter.

In accordance with an aspect of the disclosure, the microprism layer includes a plurality of controllable elements to direct the light output from the lamp. The controller circuitry is configured to control a state of the plurality of controllable elements.

In accordance with an aspect of the disclosure, a method of operating a vehicle headlamp is provided, wherein the vehicle headlamp includes an optical device configured to direct light received from a light source, and the method includes: controlling the light source to generate light; and controlling a plurality of controllable refractory devices to change the direction of the generated light.

In accordance with an aspect of the disclosure, the light source comprises a plurality of light emitting devices, where the step of controlling the light source to generate light includes controlling all of the plurality of light emitting devices to generate light.

In accordance with an aspect of the disclosure, the step of controlling a plurality of controllable refractory devices to change the direction of the generated light includes controlling the plurality of controllable refractory devices in an anti-glare state to direct the light away from a glare removal area in a light pattern of the vehicle headlamp.

In accordance with an aspect of the disclosure, the method further comprises the steps of detecting using a sensor another vehicle in a glare removal area of the vehicle headlamp, and controlling the plurality of controllable refractory devices in an anti-glare state in response to detecting the another vehicle.

In accordance with an aspect of the disclosure, the method further comprises the step of controlling the plurality of controllable refractory devices in another output state that is different from the anti-glare output state.

In accordance with an aspect of the disclosure, the method further comprises the step of detecting using a state of the vehicle, and controlling the plurality of controllable refractory devices in response to detecting the state of the vehicle.

In accordance with an aspect of the disclosure, the state of the vehicle is a steering state of the vehicle.

The above aspects of the disclosure describe a vehicle lamp system including solid state light sources and controllable elements to controllably beam form the light emitted from the light sources.

It will be appreciated that any of the aspects of this summary can be combined with other aspects in this summary as well as with the various embodiments described below.

### BRIEF DESCRIPTION OF THE DRAWINGS

Other advantages of the present disclosure will be readily appreciated, as the same becomes better understood by reference to the following detailed description when considered in connection with the accompanying drawings wherein:

FIG. 1 shows a schematic view of a vehicle and with a headlamp according to an aspect of the present disclosure;

FIG. 2 shows a schematic view of a headlamp according to an aspect of the present disclosure;

FIG. 2A shows a schematic view of a headlamp according to an aspect of the present disclosure, illustrating a refractory device steering a light beam in a vertical plane;

FIG. 2B shows a schematic view of a headlamp according to an aspect of the present disclosure, illustrating a refractory device steering a light beam in a vertical plane and a horizontal plane;

FIG. 2C shows a cross-sectional view of refractory device steering a light beam in response to a voltage applied to layers surrounding a liquid crystal structure, in accordance with an illustrative embodiment;

FIG. 3 shows a schematic view of a headlamp system with a headlamp according to an aspect of the present disclosure;

FIG. 4 shows a simplified schematic view of a headlamp according to an aspect of the present disclosure;

FIG. 5 shows a simplified schematic view of a headlamp according to an aspect of the present disclosure;

FIG. 6 shows a simplified schematic view of a headlamp according to an aspect of the present disclosure;

FIG. 7 shows a simplified schematic view of a headlamp according to an aspect of the present disclosure;

FIG. 8 shows a simplified schematic view of a headlamp system according to an aspect of the present disclosure;

FIG. 8A shows a front perspective view of the headlamp FIG. 8 installed on a rear vehicle surface having a shaped contour, for providing a taillight assembly, in accordance with an illustrative example;

FIG. 8B shows a top cross-sectional view of the headlamp in FIG. 8A illustrating the headlamp adhered to the vehicle body with a shaped contour, in accordance with an illustrative example;

FIG. 9 shows a simplified schematic view of a vehicle according to an aspect of the present disclosure;

FIG. 10 shows a simplified schematic view of a vehicle according to an aspect of the present disclosure;

FIG. 11 shows a schematic view of a lighting system according to an aspect of the present disclosure;

FIG. 12 shows a schematic view of a lighting system according to an aspect of the present disclosure; and

FIG. 13 is a method of controlling an optical device for a vehicle headlamp according to an aspect of the present disclosure.

### DETAILED DESCRIPTION OF EXAMPLE EMBODIMENTS

In general, example embodiments of vehicle lighting, e.g., headlamps, having solid state light sources and integrated beamforming in accordance with the teachings of the present disclosure will now be disclosed. The example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the present disclosure. In some example embodiments, well-known processes, well-known device structures, and well-known technologies are not described in detail, as they will be readily understood by the skilled artisan in view of the disclosure herein.

The terminology used herein is for describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” “top”, “bottom,” and the like, may be used herein for ease of description to describe one element's or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated degrees or at other orientations) and the spatially relative descriptions used herein interpreted accordingly.

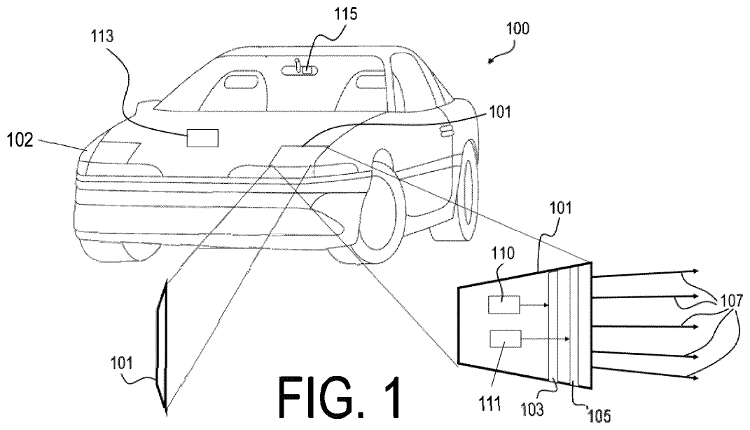

FIG. 1 shows a schematic view of a vehicle 100 and with a thin headlamp 101 with solid state components (e.g., an ultrathin headlamp assembly). Vehicle 100 has a vehicle body 102 formed from sheet metal for example, which has a shaped profile, such as curved or flat for providing a support structure upon which a thin headlamp 100 is attached. The vehicle 100 can include one or more headlamps 101 that emit light to illuminate the region in front of the vehicle. The headlamps 101 can illuminate the roadway as well as structures, such as oncoming vehicles, roadway, road signs, in front of the vehicle. The headlamps can include a matrix of hundreds or thousands of solid state light emitters 103. The headlamps can include solid state, e.g., a plurality of light emitting diodes. A lens 105 optically coupled to the emitting side of the emitters 103. The lens 105 is an optical device configured to adjust distribution of rays of light from the matrix of light emitters 103. The lens 105 can operate means of refraction effects occurring at a first, input surface to which rays of light from the emitters strike and a second, output surface from which rays of light 107 emerge. The lens 105 can include a plurality of individually controllable microlenses with each light emitter being associated with a single microlens.

Circuitry is provided to control operation of the vehicle lamp. A light driver 110 controls each of the emitters 103 in the matrix, to individually activate and cause the emitters to emit light. The light driver 110 includes circuitry to process input according to instructions to generate light commands for controlling the matrix of light emitters 103. A lens driver 111 drives each of the micro lenses in the lens 105 to control the direction of the light ray from each emitter. The lens driver 111 includes circuitry to process input according to instructions to generate lens commands for controlling the microlens in the lens 105. A body control module (BCM) 113 coordinates different operations of the headlamp(s) 101 by sensing the environment and other sensed signals in the vehicle.

The vehicle 100 can include a light sensor 115, which can sense the ambient light and light from oncoming vehicles, e.g., reflected light from the headlamps 101 or light emitted by the oncoming vehicle. The light sensor 115 can send light related information in an electrical signal to BCM 113.

The BCM 113 is in electrical communication with the light sensor 115 and the light driver 110 and the lens driver 111. The BCM 113 can process the light information signals from the light sensor 115 to control operation of the light emitters 103 and the lens 105, e.g., through control signals to the drivers 110, 111.

In an example embodiment, the headlamp 101 is ultrathin, e.g., one inch or less of less than ¼ inch in thickness. The use of solid state layers including the matrix of light emitters 103 and lens 105 allows the headlamp 101 to be ultrathin.

In an example embodiment, the matrix of light controlling devices 105 are solid state devices, lenses, prisms, or the like. The light controlling devices 105 are optically coupled to the matrix of light sources 103 to beam form the light 107 emitted from the lamp 101. In an example embodiment, the matrix of light controlling devices 105 is a one-to-one match with the matrix of light sources 103. In an example embodiment, the matrix of light controlling devices 105 is a one-to-a small number (N) match with the matrix of light sources 103. The small number N can be equal to or less than sixteen, equal to or less than eight, equal to or less than four, or equal to or less than two.

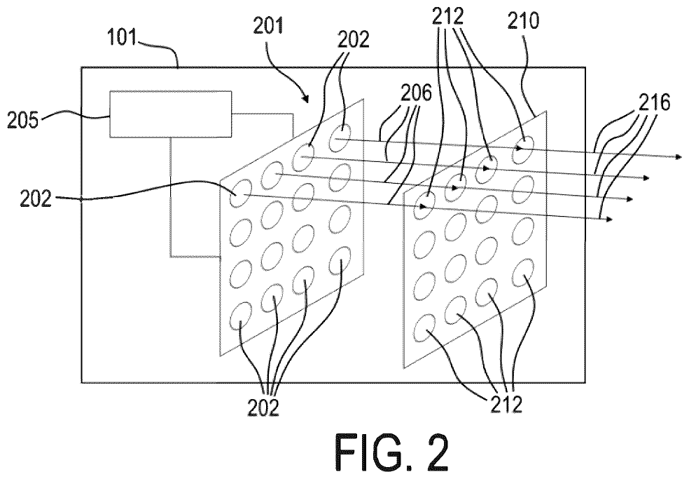

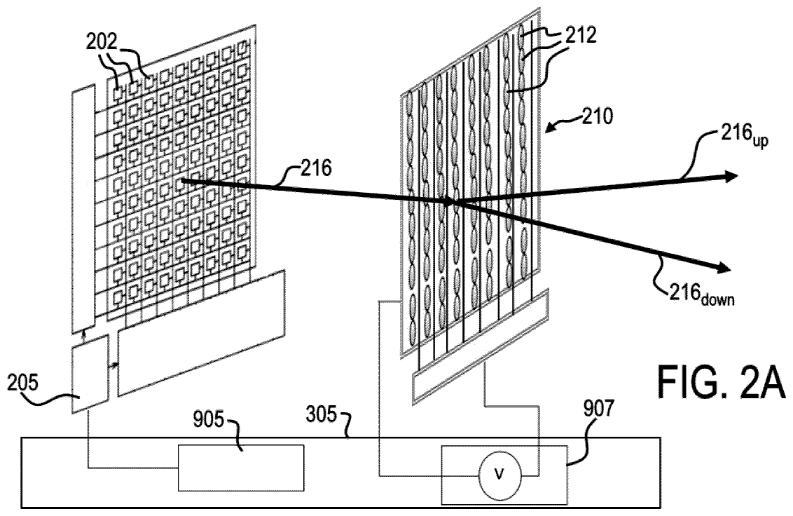

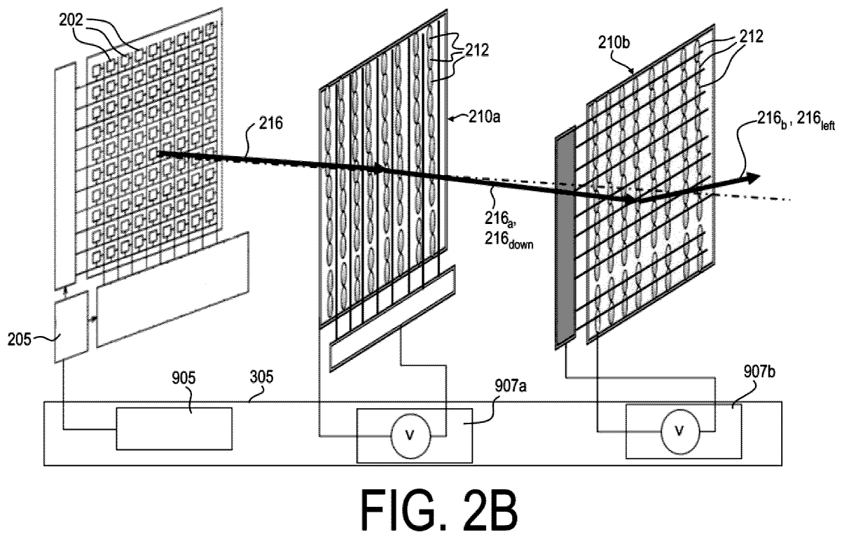

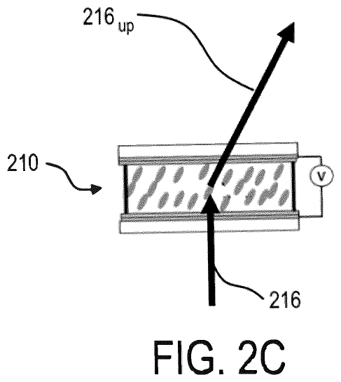

FIG. 2 shows a schematic view of a headlamp 101 according to an aspect of the present disclosure. A matrix of individually addressable light sources 201 are positioned in the headlamp 101. The matrix 201 can include a plurality of solid state light sources 202, e.g. light emitting diodes. A light source array controller 205 is connected to the matrix and controls operation of the each of the light sources 202 (e.g., using a vertical driving circuit and a horizontal driving circuit as shown in FIGS. 2A and 2B). The controller 205 includes logic circuitry and signal drive circuitry to send control signals to any individual one of the light sources and activate it to emit light. Each light source 202 when activated emits light 206. For ease of illustration, the top row of the light sources 202 is illustrated as emitting light 206. It will be further recognized that the FIG. 2 embodiment shows a reduced number of light sources 202 for ease of illustration. It is within the scope of the example embodiment shown in FIG. 2 to include hundreds, thousands, millions of light sources 202. The controller 205 can also vary light source output (e.g., control individual light source luminance) as described below.

A lens 210 is optically coupled to the emission side of the matrix 201. The lens includes a plurality of individual light refractors 212. In an example embodiment, the lens is close to the light emitting matrix such that light that enters each light refactor 212 is from a single one of the light sources 202. The light refractors 212 can be microprisms, microlenses, beam splitters, or the like. The light refactors 212 can include a plurality of microelectromechanical (MEMS) devices systems. The light refractors 212 can be micro-optical devices formed using a LIGA (Lithographie, Galvanoformung, Abformung) process in the body of a base polymer, e.g., Polymethyl methacrylate. In an example embodiment, the light refactors 212 are fixed. In an example embodiment, one or more of the light refractors 212 is different than other light refractors. The top row of light refractors can have a larger refractive index than the lower rows of light refractors 212. Each subsequent row of light refractors 212 in the lens can have a lower index of refraction. The columns of the light refactors 212 in the lens 210 can also vary in index of refraction. The lens 210 can also be a Fresnel lens. In operation, the refractors 212 individually receive light from an associated light emitter 202 at an input side and refract the light to output individual light beams 216 from an output side. Each light beam 216 is individually focused.

In an example embodiment, the light refactors 212 are controllable and individually addressable. The light refactors can each be a liquid crystal lens than can be rotated based on an applied electrical signal or electrical field. A controller (e.g., lens driver 111) can control the light refactors 212. In an example, the light refactors 212 can block the light beam for exiting the lens. In an example, the light refactors 212 can redirect the light beam in a controllable manner.

FIG. 2A illustrates a light beam emitted 216 from a single light emitter element 202 and steered by a light refractor element 212 in a single plane, for example in a vertical plane, such as upwards or down wards. A lens assembly 210 illustratively includes a bottom substrate layer having a planar electrode while the top layer has multiple electrodes with different voltages applied thereto according to voltage applied by lens controller 907 which may individually control the voltage of each electrode (e.g., via an electrode driving circuit) to steer the light of the light emitter element 202.

FIG. 2B illustrates a light beam emitted from a single light emitter element 202 and steered by a light refractor element 212 in multiple planes, for example vertically upwards or downwards, and laterally or horizontally. A lens assembly 210 illustratively includes two lens subassemblies 210a, 210b, each having bottom substrate layer having a planar electrode while the top layer has multiple electrodes with different voltages applied thereto according to voltage applied by lens controllers 907a and 907b, which may individually control the voltage of each electrode (e.g., via a vertical electrode driving circuit, and a horizontal electrode driving circuit, respectively) to steer the light of the light emitter element 202. As illustrated, two lens subassemblies 210a, 210b have the electrodes arranged perpendicular to each other for controlling the refractory elements 212 to steer light first within a vertical plane (216a) and subsequently in a horizontal plane (216b). Two lens subassemblies 210a, 210b may be provided as one assembly such that light emitted by the light emitter elements 202 may be steered by aligned light refractor elements 212 of each of the subassemblies 210a, 210b. It is recognized that multiple light refractor elements 212 may be employed to steer the light beam 216.

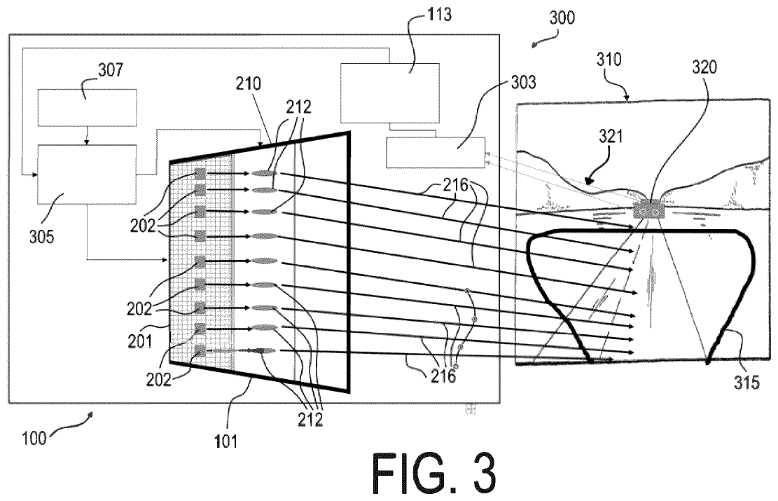

FIG. 3 shows a schematic view of a headlamp system 300 with a headlamp 101 according to an aspect of the present disclosure wherein the headlamp 101 assembly uses matrix lighting beam steering. The headlamp 101 includes a housing in which a matrix of light sources 201 is provided. A lens assembly 210 is positioned in the housing and optically coupled to the matrix of light sources 201. The lens assembly 210 includes a plurality of controllable refractory devices 212, which receive light output from the light sources 201 and refract the light to output light beams 216 from the headlamp 101. In an example embodiment, the refractory devices 212 can be liquid crystal lenses with crystals aligned with the matrix of light sources 201. One or more of the refractory devices 212 have a refractory index that is different from other refractory devices 212. The light beams 216 exit the headlamp 101 and illuminate an area 315, e.g., at the front of vehicle, and can include the roadway and areas adjacent the roadway. By controlling the status of the individual lenses 212, the light beams 216 are controlled and the illuminated area 315 can be changed. The light beams 216 can be narrowed together to achieve a low beam effect. The light beams 216 can be widened to a high beam effect.

As described herein the lens assembly 210 can be controllable to change the direction of the light beams 216 from the lamp 101. The vehicle 100 can include an imaging device, e.g., camera 303, to image the environment 315 that is illuminated or will be illuminated by the lamp 101. The imaging device can be a visible light camera and non-visible light sensors, e.g., receive light from the environment. The imaging device can also include LIDAR, RF sensors and ultrasonic sensors to determine structures in the imaged volume or environment 311. The imaging device outputs its imaging data to the BCM 113. The BCM can use the sensed information to provide a control signal to the light source controller 305 (e.g., a light driver 110). The BCM can also determine if an oncoming vehicle 320 is present (e.g., by the presence of headlamps on the oncoming vehicle 320). As shown, the vehicle 320 is in the environment 321, e.g., in the roadway and headed toward the vehicle 100. The light source controller 305 receives power from a power source 307. The power source 307 can be a battery in a vehicle. The light source controller 305 can output a control signal to the light matrix 201 to control individual ones of the light sources 202. The light source controller 305 can output a lens control signal to control the status of the lenses 212. These control signals set the direction of the light beams and the illuminated area 315. Thus, light from individual light beams 216 is steered from their corresponding pixels and can be redirected to another area in the projection pattern in lieu of shutting off each light source that is initially determined to be projecting onto an oncoming vehicle).

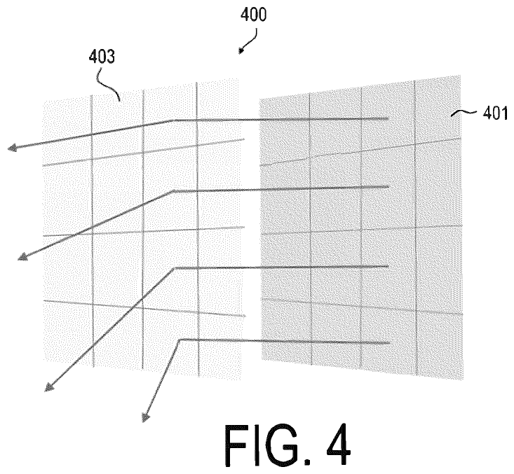

FIG. 4 shows a simplified schematic view of a headlamp 400 according to an aspect of the present disclosure. Headlamp 400 includes a matrix of light emitting sources 401, which can be individually addressable pixels. A matrix of refractory devices 403 is optically coupled to the matrix 401. In an example embodiment, a single refractory device is paired with a single light emitting pixel (e.g., a liquid crystal layer pixel is placed in front of a corresponding light emitting pixel). In an example embodiment, a plurality of light sources are optically tied to a single refractory device. The light emitting sources can be light emitting diodes in an example embodiment. The light emitting sources can be in the form of a liquid crystal display (LCD) panel, an organic light emitting diode (OLED) panel, an electro quantum dot (ELQD) panel, or the like. The matrix of refractory devices 403 can include liquid crystal lenses that are positioned in front of the matrix of light emitting sources 401 and operate to direct the light from the light sources to the roadway since light produced by each pixel can be focused on the road by the corresponding liquid crystal layer pixel in front of it. The refractory devices 403 may be a liquid crystal on silicon (LCoS or LCOS) device as illustrative examples. The matrix of light emitting sources 401 can be controlled to emit more light in a high beam effect or to emit less light in a low beam effect. This can be accomplished by turning on more light sources for the high beam and turning on fewer light sources for the low beam. In an example embodiment, the individual light source luminance can be varied to provide different luminance levels, e.g., high beam and low beam effects. The refractory devices can be individually and dynamically controlled to self-level the light output. Each light source can be individually addressable to provide anti-glare active matrix functionality without the loss of overall luminance. Individually controlling the light sources and the refractory devices can provide illumination for other objects adjacent the road, e.g., corners, intersections, signs and roadway markings, which is particularly helpful to improve visibility of signs with text. In an example embodiment, the matrices 401, 403 are thin layer structures, which are mechanically connected, and can be connected to a vehicle using an adhesive (e.g., as a sticker(s)).

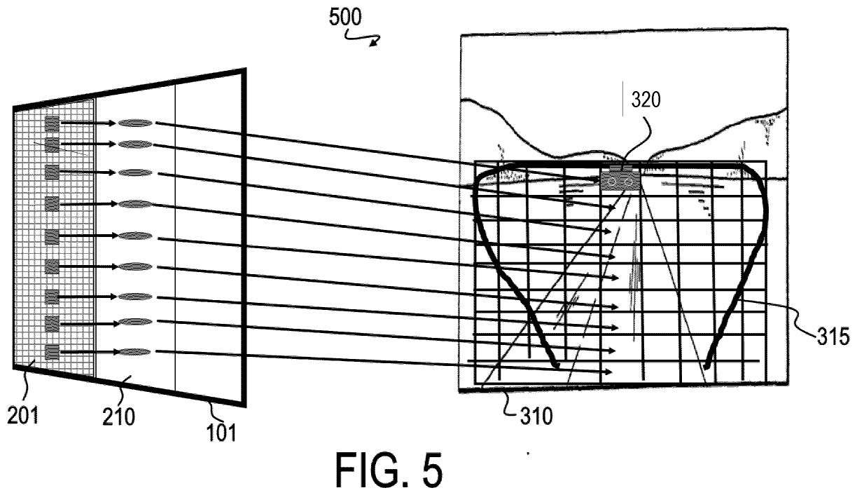

FIG. 5 shows a simplified schematic view of a headlamp system 500 according to an aspect of the present disclosure. The headlamp 101 outputs light from the light source matrix 201 once it is directed by the refractory matrix 210. In an example, the refractory matrix is a liquid crystal layer that directs light from pixels (the light source matrix) in pattern 315 ahead of vehicle. A sensor, e.g., a camera 303, along with associated processing circuitry, detects a vehicle 320 in the imaged volume or environment 310. The refractory matrix 210 is controlled to individually steer the light from each light source in matrix 201 (e.g., on a pixel-by-pixel basis), away from the oncoming vehicle 320 to reduce glare to the oncoming vehicle 320. This can be done in place of turning off some light sources. Compared to matrix lighting where individual light sources (e.g., pixels) are shut off thereby reducing the light on the road, redirecting the light uses all the light (lumens) which is steered to other useful locations rather than shutting any light sources off. The refractory devices 212 in matrix 210 can steer each light beam up or down, left or right. This will change the shapes of the illuminated area 315 but keep the same outputted lumens, but increase the luminance in the area 315. In an example embodiment, all of the light sources are on when the headlamp 101 is on.

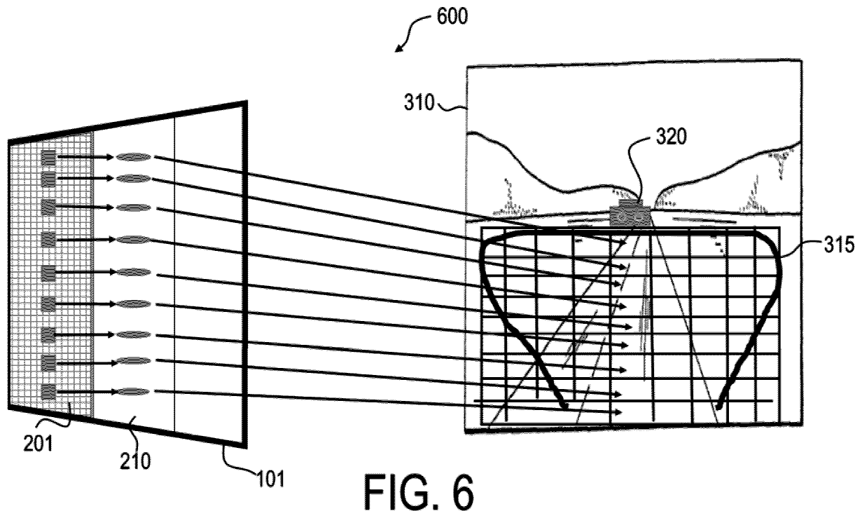

FIG. 6 shows a simplified schematic view of a headlamp system 600 according to an aspect of the present disclosure. The headlamp system 600 is the same as the headlamp system 500 shown in FIG. 5 but all of the light output from the headlamp 101 is shifted downward so as to not be directed directly at the vehicle 320. The refractory matrix 210, e.g., a liquid crystal layer (LCL), directs light downwards away from the oncoming vehicle 320. All light sources in matrix 201 are emitting light, which is not directed to the oncoming vehicle 320. The vehicle 320 is outside the illuminated area 315.

The examples described herein refer to an oncoming vehicle 320 and changing the illuminated area 315 so as to reduce glare for the oncoming vehicle. However, the present examples are not so limited. The vehicle could detect any other vehicle on the roadway, either oncoming or traveling in the same direction, and change the illuminated area to reduce glare on the other vehicle.

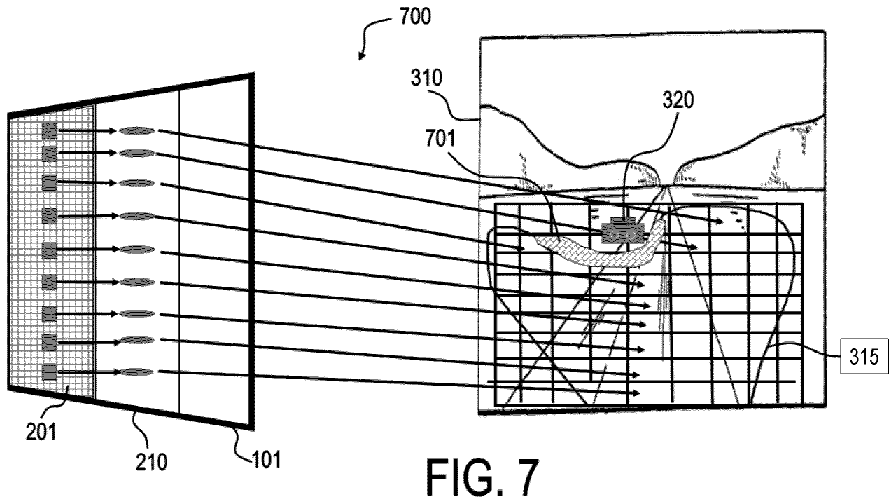

FIG. 7 shows a simplified schematic view of a headlamp system 700 according to an aspect of the present disclosure. The system 700 has all of the light sources on and emitting light, even those that have light directed at the vehicle 320 in the illuminated area 315. The refractory matrix 210 can operate to direct some light beams away from the vehicle 320. All light sources in the matrix 201 are emitting light. The light beams that would impinge the vehicle 320 are actively directed away from the vehicle 320 (e.g., left or right, and optionally down) toward adjacent roadway 701. In an example embodiment, the light sources that emit light that is directed at the vehicle 320 or will be steered away from the vehicle can reduce their light output, e.g., reduce the lumens or the luminance, to assist with glare reduction. If the light beams are being steered away from the vehicle (e.g., left, or right), the light can be used to illuminate more of the area to the sides of the road, e.g., on the side where the vehicle is traveling. The light from the vehicle lamp 101 can be steered away from the vehicle such that the vehicle 320 travels in a darkened spot in the environment 310. This darkened spot is positioned around the vehicle 320 and travels with the vehicle. Such a darkened spot will grow in area as the vehicle 320 approaches the present vehicle with the vehicle lamp 101 and disappear when the oncoming vehicle 320 is no longer in the illuminated area 315, e.g., the vehicle 320 passes the present vehicle or turns off the present roadway.

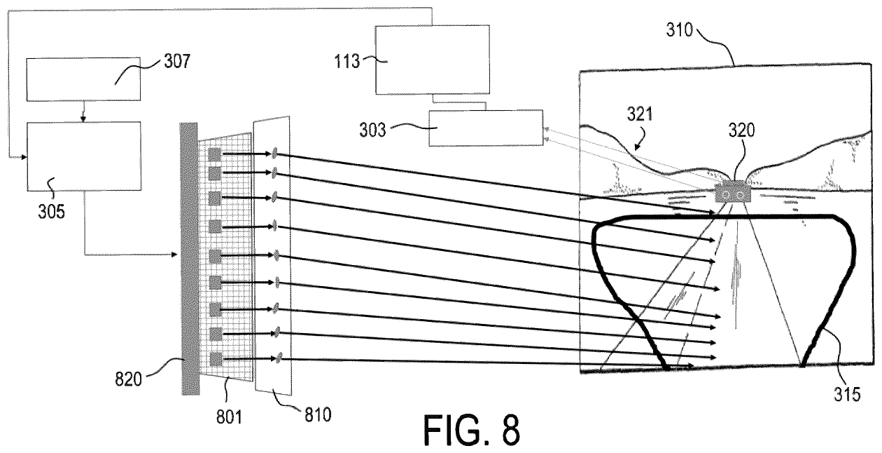

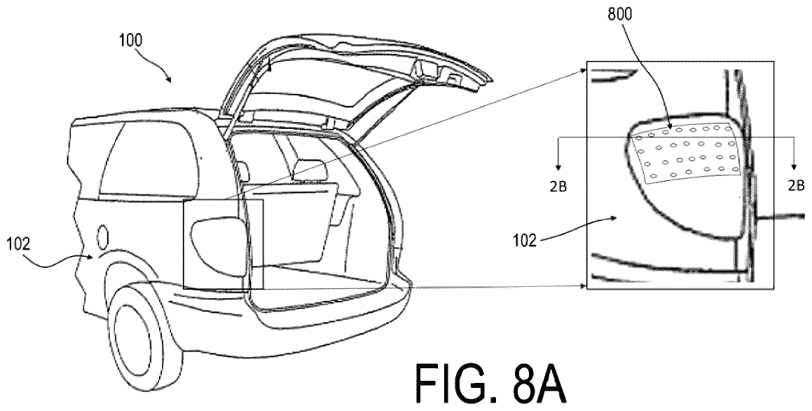

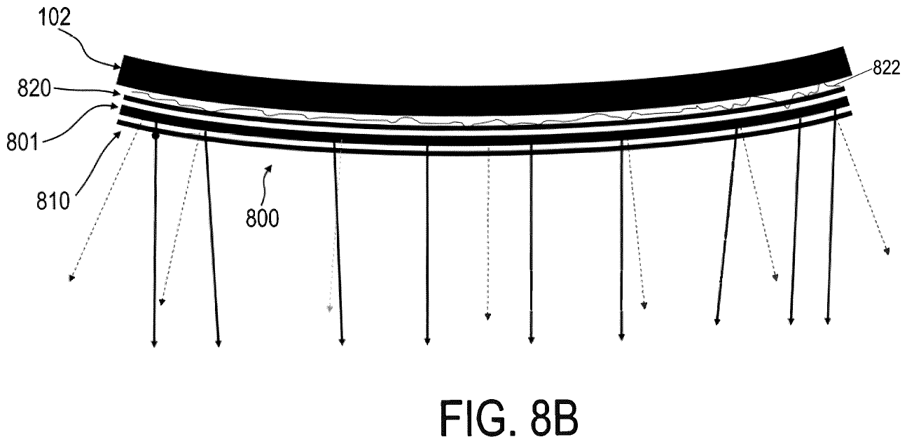

FIG. 8 shows a simplified schematic view of a headlamp system 800, according to an aspect of the present disclosure, which is similar to the headlamp system 300 (FIGS. 3-7) with the same structures being designated with the same reference numbers. Similar structures have a different most significant digit changed from a “3” to an “8.” The lamp is an ultrathin lamp assembly including a base 820, supporting a light emitting layer 801 and a refractory layer 810 that provide a flat panel emitter and fixed or dynamic beam steering. The individual light sources in the light emitting layer 801 can be individually controlled, either off/on or by varying their lumens or light output. The refractory layer 810 can be a fixed microprism array in front of each pixel or light source that focuses light in a predetermined direction, or can be implemented as a liquid crystal layer as described with reference to FIG. 3, to control the direction of the light beams from the light sources out of the lamp to illuminate the area 315. The ultrathin lamp assembly can be less than an inch, less than ½ inch or less than ¼ inch in thickness. The base 820 can include an adhesive 822 on a rear side to fix the light assembly to a vehicle. For example, the ultrathin lamp assembly can be adhered to sheet metal like a sticker, and microprisms in the refractory layer 810 can be aligned based on the curvature of the sheet metal. FIGS. 8A and 8B illustrate an installation of the headlamp system 800 to a curved vehicle surface 102. The thinness of each of the base 820, supporting a light emitting layer 801 and a refractory layer 810 provides flexibility such that the headlamp system 800 is able adopt a shape to be adhered to a vehicle surfaces 102 having different contours, such as flat or curved. FIG. 8B illustrates that the refractory layer 810 can be configured such that the light emitted by the light emitting layer 801 can be steered according to the contours of the vehicle surface 102. As shown in FIG. 8B by the dashed lines, the light emitted without such a configuration may be projected from the light emitted by the light emitting layer 801 in a direction perpendicular to the vehicle surface 102, whereas providing the refractory layer 810 to steer the emitted light to compensate for the contoured surface allows the light to be focused as desired as represented by the sold lines, for example rearward, or downward the vehicle 10, or in other directions, as desired for the application. For example, the light emitting layer 801 can be configured to provide backup reverse lighting, can be directed downwardly. For example, light emitted upwardly as a result of a curved profile of the vehicle body 102 can therefore be directed downwardly.

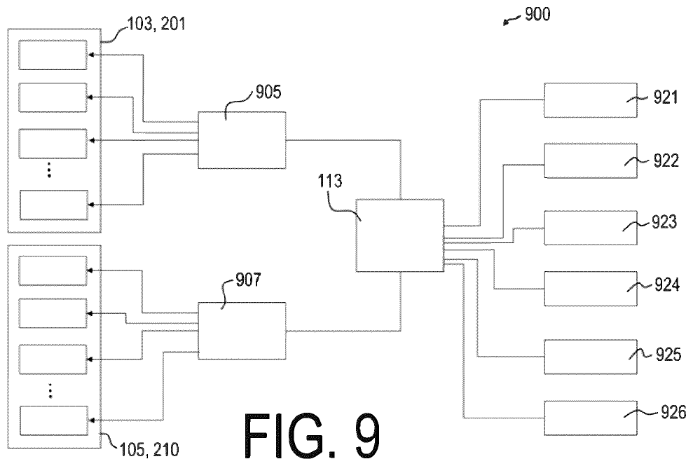

FIG. 9 shows a simplified schematic view of a vehicle 100 according to an aspect of the present disclosure. The vehicle 100 includes a lamp side and a vehicle side, which are connected by a vehicle communication channel 903, e.g., wiring or the controller area network (CAN) bus. The lamp side includes a light controller 905 to control operation of each of the light sources in the light array or matrix 103, 201. The lamp side also includes the lens controller 907, which controls operation of the refractory devices, here lenses, to control the direction of the light emitted from the lamp side. The BCM 113 is on the vehicle side and sends control signals to both the light controller 905 and the lens controller 907. The BCM 113 includes processing circuitry that is operably connected to a memory device(s). Task instructions for the BCM are stored in memory and loaded to the processing circuitry. The BCM 113 receives sensed input values from various vehicle sensors, e.g., a steering angle sensor 921, a camera 922, a light sensor(s) 923, a speed sensor 924, a LIDAR 925, driver settings 926, and others. The BCM 113 applies the instructions to the input and output commands for the light controller 905 and the lens controller 907, which in turn apply their own instructions to generate control signals applied to the light matrix 103, 201 and the refractory matrix 105, 210, respectively.

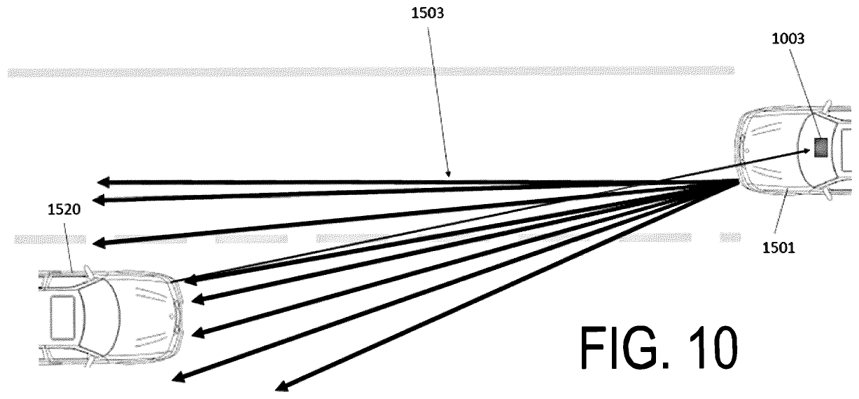

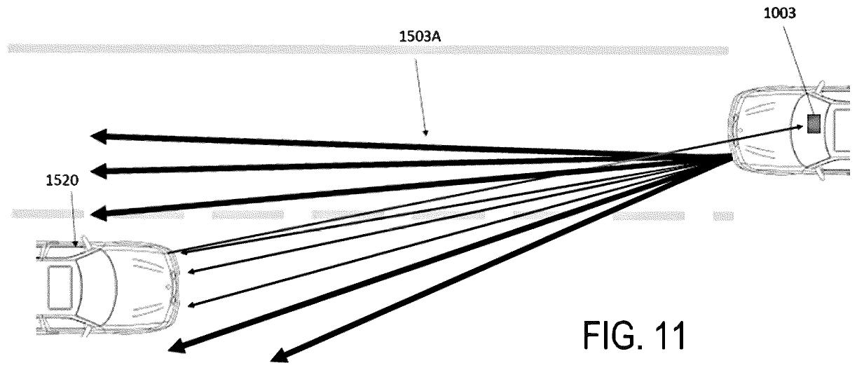

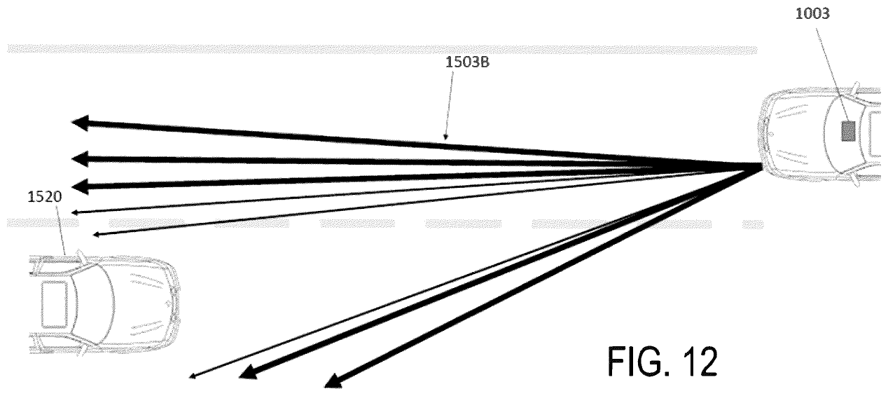

FIGS. 10-12 show the operation of the vehicle lamp system from above. A vehicle 1501 is traveling on a roadway and is emitting a light pattern 1503 according to the systems and methods described herein to illuminate the environment in front of the vehicle 1501. The light pattern 1503 includes a plurality of light beams projected from the light sources 201 and controlled by the lenses 212. The vehicle 1501 includes an imaging device 1003, e.g., a camera, to sense an oncoming vehicle 1520. The vehicle 1501 senses the oncoming vehicle 1520 and changes the light pattern to light pattern 1503A. The light pattern 1503A (FIG. 11) differs from light pattern 1503. The difference can be the light beams directed at the oncoming vehicle 1520 are dimmed or turned off. In an example embodiment, the difference is the light beams that would be directed at the vehicle 1520 are steered to not impinge the vehicle. The steered light beams 1503B are illustrated in FIG. 12 with reduced thickness and not impinging the vehicle 1520 as steered by the lens assembly 210 in accordance with the exemplary examples herein.

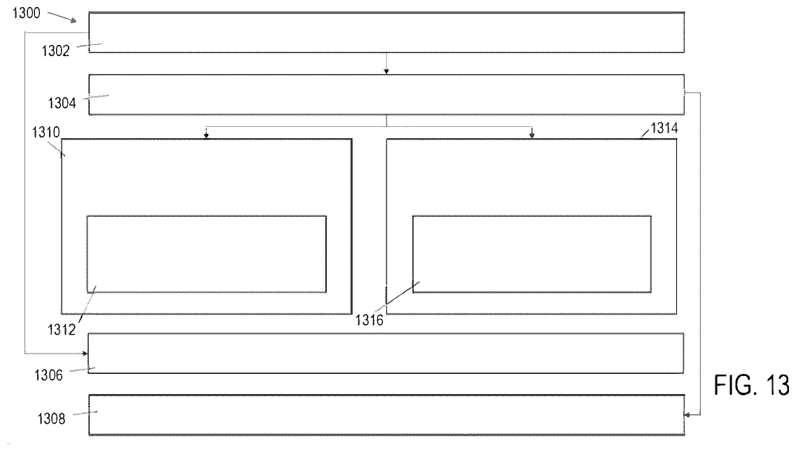

FIG. 13 is an illustrative example of a method (1300) of controlling an optical device for a vehicle headlamp, in accordance with example of the present disclosure. A controller 305 is configured to control the light source 103 in the headlamp (e.g., a matrix 201 of solid state light sources 202 such as LEDs) to generate light (step 1302) via a light driver 110, and control a plurality of controllable refractory devices 105 (e.g., a matrix of microlenses or prisms) to change the direction of the generated light (step 1304) via a lens driver 111, for example. In accordance with an example embodiment, the controller 305 can control all of the LEDs 202 in the matrix 201 to generate light (step 1306). In accordance with another example embodiment, the controller 305 can also control a plurality of controllable refractory devices 105 in an anti-glare state to direct the light away from a glare removal area in a light pattern 315 of the vehicle headlight (step 1308). With continued reference to the step 1304, the controller 305 can be configured in accordance with an example embodiment to detect (e.g., using a sensor 921, 922, 923, 924, 925 and the like) another vehicle 320 in a glare removal area of the vehicle headlight, and control the plurality of controllable refractory devices 105 to operate in an anti-glare state in response to detecting the another vehicle 320 (step 1310). Further, the controller 305 can be configured in accordance with an example embodiment to control the plurality of controllable refractory devices 105 to operate in another output state that is different from the anti-glare state (step 1312). Alternatively or in addition to step 1312, the controller 305 can be configured in accordance with an example embodiment to detect a state of the vehicle (e.g., using a sensor 921, 922, 923, 924, 925, or driver settings 926) and control the plurality of controllable refractory devices 105 in response to detecting the state of the vehicle (step 1314). For example, the controller 305 can detect the steering state of the vehicle (step 1316) and control the refractory devices 105 accordingly.

The foregoing description of the embodiments describes some embodiments with regard to lighting systems for vehicles. These are used for convenience of description. The present disclosure is applicable to solid state lights requiring a controllable lens to steer light rays emitted from the lamp.

Embodiments of the present disclosure may improve a vehicle headlamp by providing a light, thin device that can be applied to the vehicle. The headlamp can include a matrix of light emitters with each paired to a microlens. The light emitters can be individually controlled. A plurality of the microlenses can be controlled to guide the light rays emitted from the headlamp. For example, some microlenses can alter the direction of the light rays to change the output from an expanded light beam (e.g., a high beam) to a narrowed beam (e.g., a dimmed beam). However, the total output of the emitters is not reduced. That is, the headlamp can continue to output the same lumens. This can hold solid state light emitters in an optimal state, e.g., the driving electrical signal that holds the solid state in its emitting state may be less (voltage and/or current) than the electrical signal to turn the emitter on.

The foregoing description of the embodiments has been provided for purposes of illustration and description. It is not intended to be exhaustive or to limit the disclosure. Individual elements, assemblies/subassemblies, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A vehicle lamp, comprising:
a matrix of solid state light emitters;
a lens optically connected to the matrix of solid state light emitters, wherein the lens includes a plurality of controllable refractory devices; and
a controller to control the matrix of solid state light emitters and the plurality of refractory devices.

2. The vehicle lamp of claim 1, wherein the solid state light emitters) are each individually controllable.

3. The vehicle lamp of claim 2, wherein the refractory devices are microlenses.

4. The vehicle lamp of claim 1, wherein the refractory devices are each individually controllable to control the direction of the light beams from the lamp.

5. The vehicle lamp of claim 1, wherein the controller receives position information of another vehicle and controls direction of the light by controlling the refractory devices to direct light away from the another vehicle.

6. The vehicle lamp of claim 1, wherein the refractory devices include liquid crystal lenses.

7. The vehicle lamp of claim 1, wherein the solid state light emitters are controlled to adjust the lumens being output from each light source.

8. A thin vehicle lamp, comprising:
a base layer configured to be adhered to a vehicle component;
a thin film active layer including a matrix of solid state light emitters;
a microprism layer optically connected to the matrix of solid state light emitters, wherein each solid state emitter is optically coupled to at least one microprism of the microprism layer to control the direction of the light emitted from the lamp; and
controller circuitry to control the matrix of solid state light emitters.

9. The lamp of claim 8, wherein the controller circuitry controls the on state of each solid state emitter.

10. The lamp of claim 9, wherein the controller circuitry receives sensed signals from vehicle sensors and controls operation of each solid state emitter.

11. The lamp of claim 9, wherein the microprism layer includes a plurality of controllable elements to direct the light output from the lamp, and wherein the controller circuitry controls a state of the plurality of controllable elements.

12. A method of operating a vehicle headlamp, the vehicle headlamp including an optical device configured to direct light received from a light source, the method including:
controlling the light source to generate light; and
controlling a plurality of controllable refractory devices to change the direction of the generated light.

13. The method of claim 13, wherein the light source comprises a plurality of light emitting devices, and wherein the step of controlling the light source (103) to generate light includes controlling all of the plurality of light emitting devices (202) to generate light.

14. The method (1300) of claim 13, wherein the step of controlling a plurality of controllable refractory devices to change the direction of the generated light includes controlling the plurality of controllable refractory devices in an anti-glare state to direct the light away from a glare removal area in a light pattern of the vehicle headlamp.

15. The method of claim 13, further comprising the steps of detecting using a sensor another vehicle in a glare removal area of the vehicle headlamp, and controlling) the plurality of controllable refractory devices in an anti-glare state in response to detecting the another vehicle.

16. The method of claim 15, further comprising the step of controlling the plurality of controllable refractory devices in another output state that is different from the anti-glare output state.

17. The method of claim 13, further comprising the step of detecting (1314) using a state of the vehicle, and controlling the plurality of controllable refractory devices in response to detecting the state of the vehicle.

18. The method of claim 17, wherein the state of the vehicle is a steering state of the vehicle.
